(19) United States
(12) Patent Application Publication
(10) Pub. No.: US 2024/0038605 A1
(43) Pub. Date: Feb. 1, 2024

(54) SEMICONDUCTOR STRUCTURE WITH TESTLINE AND METHOD OF FABRICATING SAME

(71) Applicant: Taiwan Semiconductor Manufacturing Company, Ltd., Hsin-Chu (TW)

(72) Inventors: Yu-Ching Chiu, Hsinchu City (TW); Chih-Kuang Kao, Chu-pei City (TW); Huei-Wen Yang, Hsinchu (TW)

(21) Appl. No.: 18/308,982

(22) Filed: Apr. 28, 2023

Related U.S. Application Data
(60) Provisional application No. 63/393,137, filed on Jul. 28, 2022.
(60) Provisional application No. 63/382,148, filed on Nov. 3, 2022.

(51) Int. Cl. H01L 21/66

(52) U.S. Cl. CPC H01L 22/32; H01L 22/14; H01L 29/775

(57) ABSTRACT

A testline structure of a semiconductor device includes a substrate layer, a frontside insulating layer atop the substrate layer, a backside insulating layer under the substrate layer, and a probe pad structure vertically extending through the frontside insulating layer, the substrate layer, and the backside insulating layer. The probe pad structure includes a frontside probe pad in the frontside insulating layer and a backside probe pad in the backside insulating layer.

### PRIORITY

This claims the benefits to U.S. Provisional Application Ser. No. 63/393,137 filed Jul. 28, 2022 and U.S. Provisional Application Ser. No. 63/382,148 filed Nov. 3, 2022, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Recently, backside power rails have been introduced in an effort to reduce resistance in IC power routing and reduce voltage drop across power rails. Conventionally, transistor devices (e.g., fin field-effect transistor (FinFET) device and gate-all-around (GAA) device) are built in a stacked-up fashion, having transistors at the lowest level and interconnect (vias and wires) on top of the transistors to provide connectivity to the transistors. Power rails (such as metal lines for voltage sources and ground planes) are also above the transistors and may be part of the interconnect. As the integrated circuits continue to scale down, so do the power rails. This leads to increased voltage drop across the power rails, as well as increased power consumption of the integrated circuits. The implementation of backside power rails increases the number of power rails available in an IC for directly providing power to transistor devices. It also increases the gate density for greater device integration than existing structures without the backside power rails. On the other hand, existing testline structures are still formed on top of the transistors, without fully adopting advantages provided by the backside power rail technology. Therefore, although existing approaches in testline structures have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a top view of a semiconductor device with testlines, in accordance with some embodiments of the present disclosure.

FIGS. 2A and 2B schematically illustrate top views of testline structures, in accordance with some embodiments of the present disclosure.

FIGS. 3A and 3B illustrate cross-sectional views of testline structures with frontside probe pads and backside probe pads, in accordance with some embodiments of the present disclosure.

FIGS. 4A and 4B illustrate cross-sectional views of a semiconductor wafer with integrated circuit components, seal rings, and testlines, in accordance with some embodiments of the present disclosure.

FIG. 5 shows a flow chart of a method of forming a semiconductor device with testlines, in accordance with some embodiments of the present disclosure.

FIGS. 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, and 16C illustrate cross-sectional views of a portion of a testline structure at various stages of the method in FIG. 5, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term encompasses numbers that are within certain variations (such as +/−10% or other variations) of the number described, in accordance with the knowledge of the skilled in the art in view of the specific technology disclosed herein, unless otherwise specified. For example, the term “about 5 nm” may encompass the dimension range from 4.5 nm to 5.5 nm, 4.0 nm to 5.0 nm, etc.

The present disclosure generally relates to the testing of integrated circuits (ICs), and more particularly to the testline structure on an integrated circuit wafer substrate for wafer acceptance testing (WAT), process control monitoring (PCM), and/or failure analysis (FA) needs.

In integrated circuit manufacturing, a semiconductor wafer typically contains a plurality of testlines in the scribe line area between adjacent wafer dies. Each testline includes a number of devices under test (DUTs), which are structures similar to those that are normally used to form the integrated circuit products in the wafer die area. DUTs are usually formed in the test pattern areas between adjacent probe pads on a testline at the same time as the functional circuitry using the same process steps. Probe pads are usually flat, square metal surfaces on a testline through which test stimuli can be applied to corresponding DUTs. Parametric test results on DUTs are usually utilized to monitor, improve and refine a semiconductor manufacturing process. Yield of test structures on a testline is often used to predict the yield of functional integrated circuitries in the die area.

Following the continuous scale down in device feature sizes in an integrated circuit in order to meet the increasing demand of integrating more complex circuit functions on a single chip, power rails in an integrated circuit need further improvement in order to provide the needed performance boost as well as reducing power consumption. Power rails (or power routings) on a back side (or backside) of a structure, which contains transistors (such as fin field-effect transistors (FinFETs) and/or gate-all-around (GAA) transistors) in addition to an interconnect structure (which may include power rails as well) on a front side (or frontside) of the structure, is also referred to as backside power rails. The implementation of backside power rails in IC manufacturing increases the number of metal tracks available in the structure for directly powering up transistors. It also increases the gate density for greater device integration than existing structures without the backside power rails. The backside power rails may have wider dimension than the first level metal (M0) tracks on the frontside of the structure, which beneficially reduces the power rail resistance.

On the other hand, the implementation of backside power rails has imposed new demands on the existing parametric testline structure. One of these demands is that testlines corresponding to backside power rail technology better provide backside testing structures to meet the test needs for advanced semiconductor devices and complex integrated circuits, such as providing backside probe pads to land probe needles from backside. Further, in view of the trends described above and other issues facing conventional testline structures and the ever-increasing testing tasks demanded by advanced technologies, there is a need for improved testline structures capable of housing more DUTs on a shrunk testline area, such as housing more DUTs on the backside of the structure.

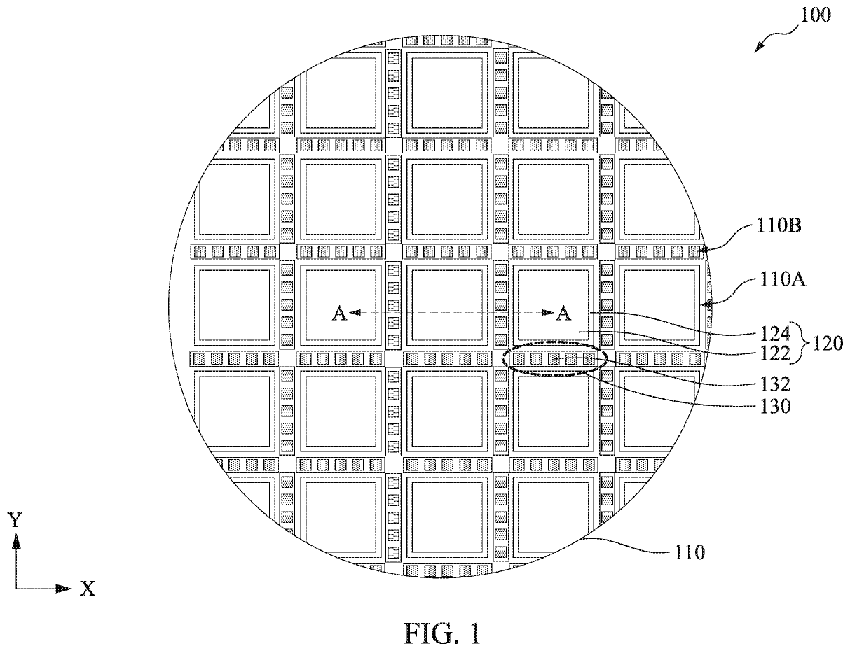

FIG. 1 schematically illustrates a top view of a semiconductor device including integrated circuit components, seal rings, and testline structures, in accordance with some embodiments of the disclosure. In FIG. 1, the semiconductor device may be a semiconductor wafer 100 including a base 110 having die regions 110A and scribe line regions 110B, dies 120 (including circuit region 122 and seal rings 124), and testline structures (or testlines) 130 (including probe pads 132). The dies 120 and the testlines 130 are fabricated on the base 110. In some embodiments, each of the dies 120 may include integrated circuits therein and the integrated circuits may be formed by a plurality of components connected in required connection relationship to construct the specific circuits. In some embodiments, each of the dies 120 may be sealed with integrated circuits therein surrounded by the seal ring 122. The die regions 110A may refer to the regions where the dies 120 are. The scribe line regions 110B may be distributed in between the die regions 110A and may forms grid-like distribution in the semiconductor wafer 100. The testlines 130 may be disposed on a layout region within the scribe line regions 110B and positioned between the dies 120. The probe pads 132 are also disposed on the scribe line regions 110B.

In some embodiments, the testlines 130 may be formed on the semiconductor wafer 100 by using the processes and steps for forming the integrated circuits in the dies 120. Accordingly, the testlines 130 and the dies 120 both include multiple components such as transistors and interconnection wiring such as redistribution layers may be formed on the base 110 for connecting the components based on the required design. After the transistors and the required wirings in the dies 120 are fabricated on the semiconductor wafer 100, a test such as a wafer acceptance test (WAT) may be performed on the testlines 130 to determine the acceptance rate of the semiconductor wafer 100. In some embodiments, the WAT may be performed before the dies 120 are completed so that the WAT may be an inter-metal WAT. In other words, after passing the inter-metal WAT, further fabrication processes may be performed on the semiconductor wafer 100. In some embodiments, the WAT may be performed after the first level metal layer (M1) or the second level metal layer (M2) (the former layers among the metal layers in the interconnect structure) is formed. On the contrary, if the inter-metal WAT is not passed, the semiconductor wafer 100 may be considered as a failure wafer and no further fabrication process is performed thereon. Accordingly, the inter-metal WAT may facilitate to inspect the failure wafer in the middle stage of the fabrication process. In the wafer acceptance test, the testlines 130 may be electrically connected to an external circuit or probes of a probe card via the probe pads 132 to check the quality of the integrated circuit process. Once the semiconductor wafer 100 passes the test, the subsequent process for fabricating the final product may be performed to form the required final product. For example, the dies 120 may be packaged and singulated by cutting the semiconductor wafer 100 along the scribe line regions 110B to obtain individual dies 120. The cutting the semiconductor wafer 100 along the scribe line regions 110B, the singulation process, may also separate the testlines 130 from the dies 120 so that the singulated die 120 in the final product may not include the testlines 130. Alternatively, depending on the scribing width during the singulation process and location of the scribes, partial or full of the testlines 130 may remain with the singulated die 120 and is packaged together with the singulated die 120.

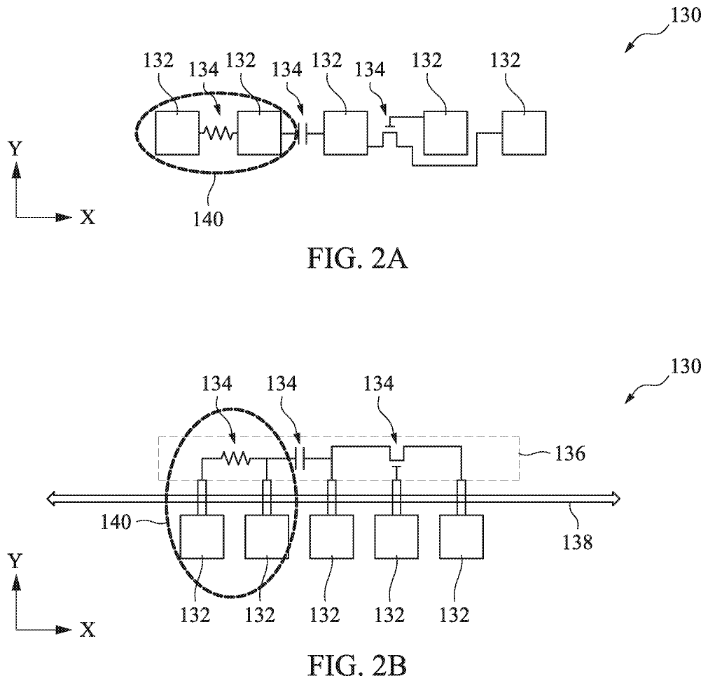

FIG. 2A schematically illustrates a top view of an exemplary testline 130, in accordance with some embodiments of the disclosure. The testline 130 is formed in a scribe line region 110B between adjacent dies 120. Each testline is made up by a serial number of aligned probe pads 132. Each probe pad 132 has a square shape and may be made from metal or other electrically conductive materials (e.g., AlCu or NiPdAu—Cu). In some alternative embodiments, the probe pads 132 from the top view may be shaped as a circular pattern. The disclosure does not construe the shape of the probe pads. Area of a probe pad 132 may range from about 100 um² to about 10,000 um². Probe pads 132 on the testline 130 are electrically connected to a plurality of DUTs 134 formed between adjacent probe pads. Pluralities of testlines with different DUTs are formed in scribe line regions across the semiconductor wafer 100. The DUTs 134 are test structures in the form of resistors, capacitors, inductors, diodes, transistors, or the like, designed to measure device parameters, such as MOSFET Vt, contact/via chain resistance, sheet capacitance, gate oxide breakdown voltage, and the like. By studying these parameters, it is possible to monitor, improve and refine a semiconductor production process. In a testline, the number of DUTs may equal to or be less than the number of probe pads. In the illustrated embodiment, the exemplary testline 130 includes three DUTs 134, namely a first DUT in the form of a resistor, a second DUT in the form of a capacitor, and a third DUT in the form of a transistor. On the other hand, the exemplary testline 130 includes five probe pads 132. In some alternative embodiments, a testline may include dummy probe pads (not shown), which is electrically floating and not connected to any DUT.

Following the continuous scale down in device feature sizes in an integrated circuit in order to meet the increasing demand of integrating more complex circuit functions on a single chip, a similar trend has been urged upon the size and structure of a testline. That is the area of a testline must shrink with each technology generation to facilitate more wafer areas for functional integrated circuitries. On the other hand, as the continuing scale-down of device feature sizes and increased circuit complexity in an integrated circuit has imposed new demands on the testline structure such that testlines corresponding to advanced processing technology must include a large amount of DUTs of different types and dimensions to meet the test needs for advanced semiconductor devices and complex integrated circuits. FIG. 2B illustrates an alternative layout of the exemplary testline 130, which allows more testlines—thus more DUTs—to be accommodated in scribe line regions. Compared with the testline 130 in FIG. 2A where the DUTs 134 and the probe pads 132 are interleaved along a straight line, in FIG. 2B the DUTs 134 are all disposed in a DUT region 136, which is aside the probe pads 132. That is, in FIG. 2B, the DUTs 134 are gathered in a DUT region 136, and the probe pads 132 are lined up along an edge of the DUT region 136 and connected to respective DUTs 134 through metal traces. Such side-by-side arrangement better utilizes a width of a scribe line region, and allows a length of a testline to be reduced, which leads to more testlines accommodated in a scribe line region. FIG. 2B further illustrates a scribe line 138. The scribe line 138 marks where the dies 120 are singulated. The scribe line 138 may travel through the region between the DUT region 136 and the probe pads 132, such that a singulated die 120 in the final product may include the probe pads 132.

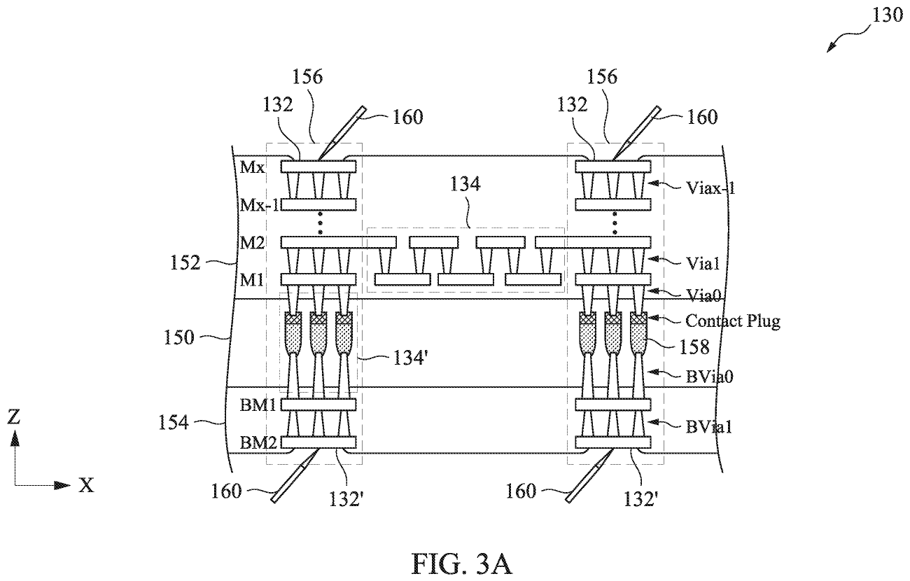

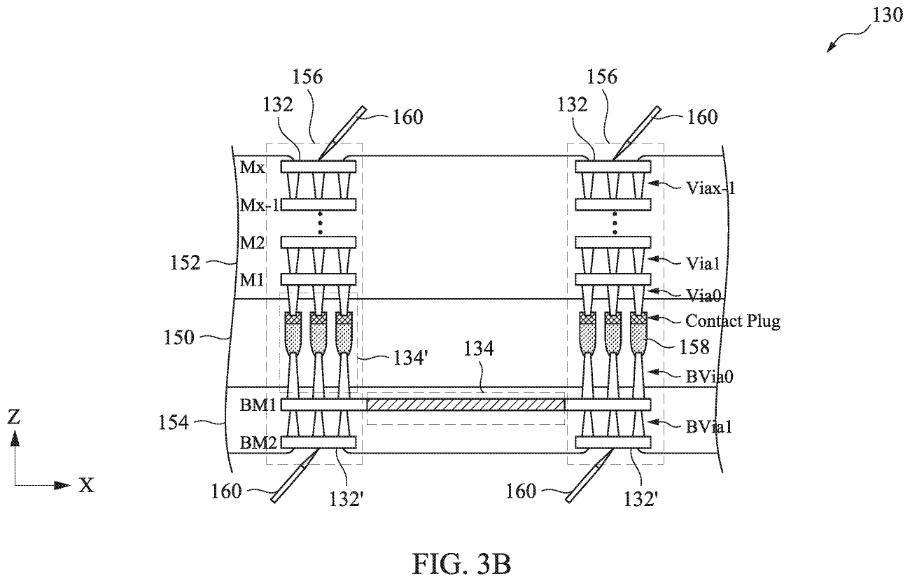

FIG. 3A illustrates a schematic cross-section view of a portion of the exemplary testline 130 (dashed circle 140 in FIG. 2A or 2B), which includes one DUT 134 and two probe pads 132 associated with the DUT 134. This portion of the testline structure comprises a substrate layer (or semiconductor substrate) 150, a frontside insulating layer 152 formed atop the substrate layer 150, a backside insulating layer 154 formed under the substrate layer 150, and a DUT 134 formed in the frontside insulating layer 152. Two probe pads 132 are electrically coupled to two terminals of the DUT 134. Each probe pad 132 has an opposing backside probe pad 132′. Thus, the probe pads 132 are also referred to as frontside probe pads. The structure extending from the frontside probe pad 132 to the backside probe pad 132′ including interconnect structures therebetween is referred to as probe pad structure 156. In a probe pad structure 156, the frontside probe pad 132 is the topmost metal piece, and the backside probe pad 132′ is the bottommost metal piece. A probe pad structure 156 is separated from an adjacent probe pad structure 156. Each probe pad structure 156 includes a stacking via structure underlying the frontside probe pad 132. The stacking via structure includes a metal piece (or referred to as metal pad) on each metal layer in the same shape as the probe pads 132 and coupled to each other through one or more vias. In some embodiments, metallic materials of the frontside probe pad 132 and the metal pieces in underneath metal layers (M1, M2, . . . Mx−1) of the stacking via structure may be different. For example, the frontside probe pad 132 may include AlCu or NiPdAu—Cu, and the metal pieces in underneath metal layers may include tungsten (W), aluminum (Al), or copper (Cu).

In the illustrated embodiment, the resistance of a via formed in a first level via layer (denoted as Via 1), which is used to make electrical connection between metal layers M1 and M2, is measured through the DUT 134. To conduct Via 1 resistance measurement with desired test precision, a via chain comprising a plurality of Via 1 is first formed between M1 and M2. Resistance of the via chain is measured and the resistance of an individual Via 1 is estimated therefrom. A via chain comprises an M2 metal piece extending from an M2 metal pad of the first probe pad structure 156, a Via 1 connecting the M2 metal piece to an M1 metal piece, and another Via 1 connecting the M1 metal piece to another M2 metal piece, and repetition of such a zig-zag pattern. The zig-zag pattern continues until an end M2 metal piece of the via chain meets an M2 metal pad of the second probe pad structure 156.

Unlike some conventional probe pad structures that is formed within the frontside insulating layer 152 only (e.g., with bottommost metal pieces starting from M1), the illustrated probe pad structure 156 includes a frontside portion formed in the frontside insulating layer 152, a backside portion formed in the backside insulating layer 154, and a middle portion formed in the substrate layer 150. The middle portion electrically connects the frontside portion and the backside portion of the probe pad structure 156. The frontside portion of the probe pad structure 156 includes a square shaped metal piece on each metal layer (e.g., M1, M2, . . . Mx−1, Mx) coupled to each other through one or more vias (e.g., Via 1, . . . Via x−1). The frontside probe pad 132 is formed on the topmost metal layer Mx. The backside portion of the probe pad structure 156 includes a square shaped metal piece on each backside meta layer (e.g., BM1, BM2) coupled to each other through one or more backside vias (e.g., BVia 1). The backside portion further includes the backside probe pad 132′ formed on the bottommost backside metal layer (e.g., BM2 in the illustrated embodiment). Thus, the probe pad structure 156 includes the frontside probe pad 132 and the backside probe pad 132′ electrically coupled to each other. In some embodiments, metallic materials of the backside probe pad 132′ and the metal pieces in other backside metal layers (e.g., BM1) may be different. For example, the backside probe pad 132′ may include AlCu or NiPdAu—Cu, and the metal pieces in BM1 may include tungsten (W), aluminum (Al), or copper (Cu).

The number of metal layers in the frontside portion of the probe pad structure 156 may be more than the number of backside metal layers in the backside portion of the probe pad structure 156. In some alternative embodiments, the number of metal layers in the frontside portion of the probe pad structure 156 may equal to the number of backside metal layers in the backside portion of the probe pad structure 156. The frontside portion is also referred to as frontside interconnect structure of the probe pad structure 156; the backside portion is also referred to as backside interconnect structure of the probe pad structure 156.

The middle portion of the probe pad structure 156 includes one or more doped epitaxial features 158, contact plugs formed atop the doped epitaxial features 158, contact vias (denoted as Via 0) connecting contact plugs and M1, and backside contact vias (denoted as BVia 0) formed under the doped epitaxial features 158 and connecting the doped epitaxial features 158 with BM1. The doped epitaxial features 158 may be source/drain features of transistors formed in a probe pad structure. Since the transistors formed in a probe pad structure do not provide circuit functions and are thus referred to as non-functional transistors. As a comparison, transistors formed as circuit components in the circuit region 122 of a die are referred to as functional transistors. As used herein, a source/drain feature may refer to a source or a drain of a device. It may also refer to a region that provides a source and/or drain for multiple devices. The combination of contact vias Via 0, contact plugs, dope epitaxial features 158, and backside contact vias BVia0 provides an electrical connection between the frontside interconnect structure and the backside interconnect structure of the probe pad structure 156.

Extra to the frontside probe pads 132, the backside probe pads 132′ provide backside probing capability of a testline structure to also conduct WAT, PCM, and/or FA tests from backside of the semiconductor wafer. During the testing process, the probe pads are electrically coupled to an external terminal through probe needles for testing. FIG. 3 illustrates four probe needles 160 probing the frontside probe pads 132 and the backside probe pads 132′ simultaneously. The probe needles 160 may be a part of a probe card that includes multiple probe needles which, for example, may be connected to testing equipment. Alternatively, a frontside probing process and a backside probing process may be performed individually and separately, such as performing a frontside testing through the frontside probe pads 132 followed by performing a backside testing through the backside probe pads 132, or vice versa. Further, the middle portion of the probe pad structure 156 can be considered as another DUT 134′ providing a test structure of measuring interconnect resistance between frontside power rails and backside power rails. By probing the frontside probe pad 132 and the backside probe pad 132′ of the same probe pad structure 156 with two probe needles 160 simultaneously, the interconnect resistance providing by the combination of contact vias Via 0, contact plugs, dope epitaxial features 158, and backside contact vias of BVia0 can be measured.

The backside probe pads 132′ also allows extra housing to accommodate more DUTs on a shrunk testline area, such as housing more DUTs on the backside of the structure. FIG. 3B illustrates such an example. The exemplary testline 130 in FIG. 3B is similar to its counterpart in FIG. 3A. One difference is that the DUT 134 is a bulky resistor formed in the backside first level metal layer (BM1) in a test pattern area between two probe pad structures 156. The bulky resistor may be made of copper in a rectangular and serpentine configuration, although other suitable metal or non-metal conductive materials, such as aluminum (Al), silver (Ag), tungsten (W), and polysilicon of various conductivities can also be used to form resistors of various shapes.

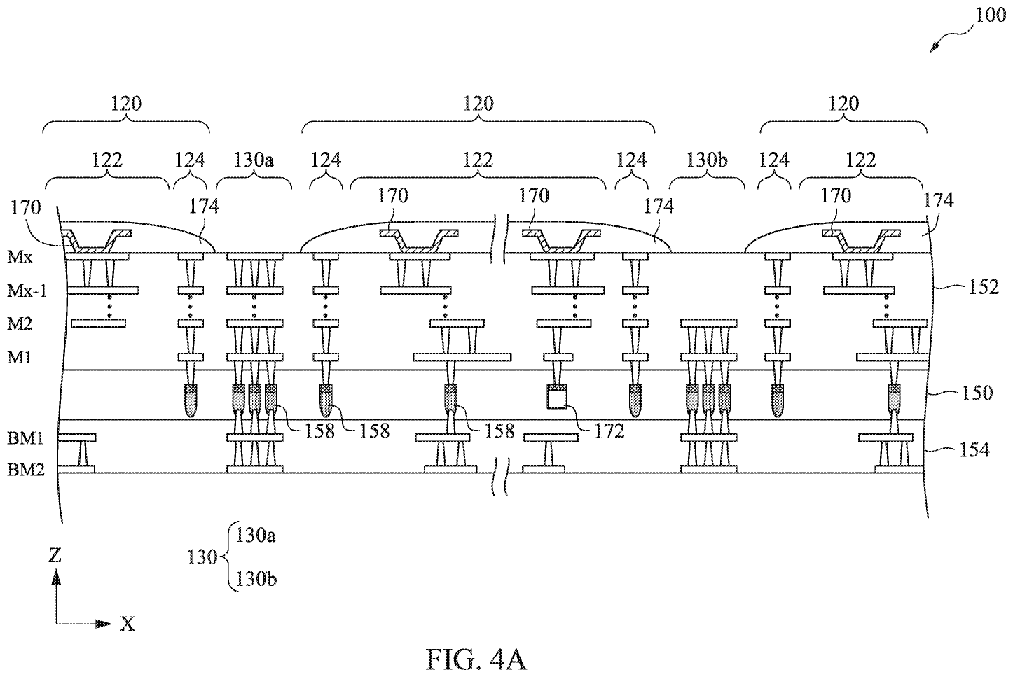

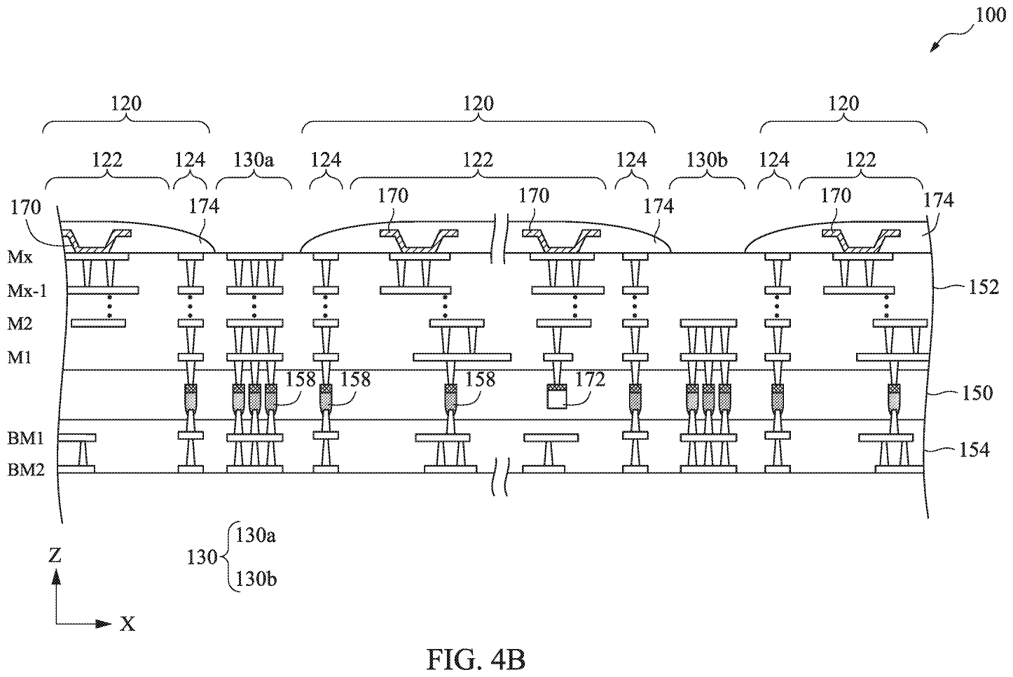

FIGS. 4A and 4B illustrate cross-sectional views of the semiconductor wafer 100 along a cutline A-A as shown in FIG. 1 in some embodiments. Referring to FIG. 4A, the semiconductor wafer 100 may include a semiconductor substrate 150, a frontside insulating layer 152 formed atop the semiconductor substrate 150, and a backside insulating layer 154 formed under the semiconductor substrate 150. The semiconductor wafer 100 may include dies 120 (including circuit region 122 and seal rings 124), and testlines 130. The seal rings 124 may encircle the circuit region 122. The testlines 130 may be disposed between the seal rings 124.

The circuit region 122 includes a variety of electrical devices, such as passive components or active components. The electrical devices are formed in and/or on the semiconductor substrate 150 and are electrically connected by interconnect structures, which are stacked and disposed through the frontside insulating layer 152, to each other or to another circuitry. In some embodiments, the interconnect structures include contact plugs, conductive lines, and vias. The interconnect structures include at least one of aluminum, copper, copper alloy, titanium, titanium nitride, tantalum, tantalum nitride, tungsten, metal silicide, combinations thereof or other suitable materials. The illustrated embodiment depicts an interconnect structure in the circuit region 122, which couples a source/drain feature 158 to a post passivation interconnect (PPI) structure 170 formed above a contact pad in the top metal layer (Mx). The interconnect structure also provides backside power rails formed in BM1 and BM2 metal layers in coupling with the source/drain feature 158. The illustrated embodiment also depicts another interconnect structure in the circuit region 122, which couples a gate stack 172 of a functional transistor to a post passivation interconnect (PPI) structure 170 formed above a contact pad in Mx metal layer.

The seal rings 124 are configured to protect the circuit region 122 from moisture degradation, ionic contamination and damage during dicing and packaging processes. The seal rings 124 are formed simultaneously with the construction of the interconnect structures in the circuit region 122. The seal rings 124 include a stacking via structure formed in the frontside insulating layer 152 and one or more source/drain features 158 coupled to the stacking via structure through contact vias. The circuit region 122 and the seal rings 124 may be covered under a passivation layer 174. In some embodiments, the seal rings 124 also include backside contacts, metal lines and vias formed in BM1 and BM2 metal layers in coupling with the source/drain features 158, such as shown in FIG. 4B.

The illustrated embodiments in FIGS. 4A and 4B also depict a first testline structure 130a and a second testline structure 130b as exemplary testline structures 130. The first testline structure 130a is substantially similar to the testline structure 130 depicted above with reference to FIG. 3 and the detail description is omitted for the sake of conciseness. The second testline structure 130b is similar to the first testline structure 130a. One difference is that the second testline structure 130b does not include higher metal layers (e.g., M5 and above). In the illustrated embodiment, the second testline structure 130b is formed of M2 and metal layers thereunder. The second testline structure 130b is for the purpose of inter-metal WAT. The inter-metal WAT may be performed after the metal layer M1 or M2 (the former layers among the metal layers in the interconnect structure) is formed. After passing the inter-metal WAT, further fabrication processes may be performed on the semiconductor wafer 100, including finishing higher metal layers in the circuit region 122, the seal ring 124, and the first testline structure 130a. The testline structures 130a and 130b may be positioned in the same scribe line region, or in two perpendicular scribe line regions adjacent a die, respectively.

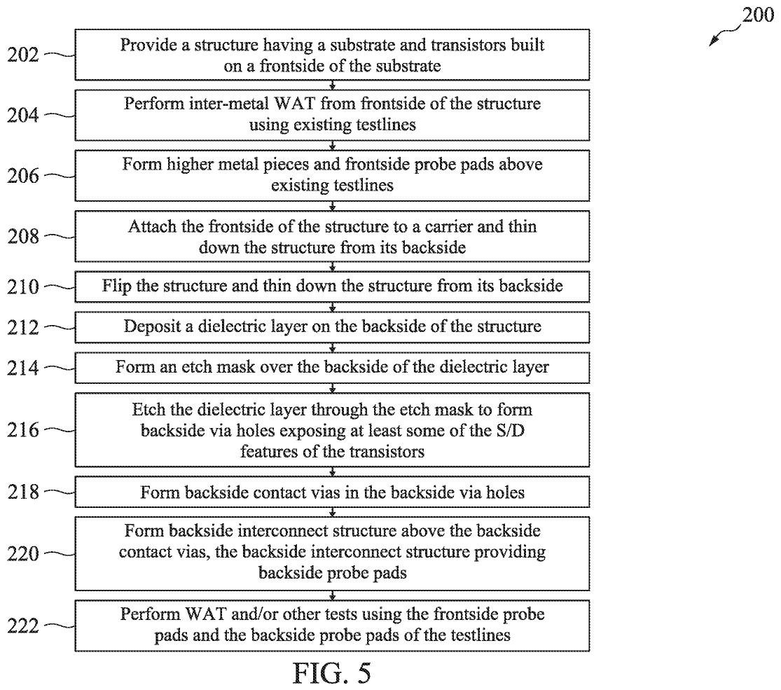

FIG. 5 is a flow chart of a method 200 for fabricating a testline structure, particularly a probe pad structure in a testline structure, according to various embodiments of the present disclosure. Additional processing is contemplated by the present disclosure. Additional operations can be provided before, during, and after method 200, and some of the operations described can be moved, replaced, or eliminated for additional embodiments of method 200.

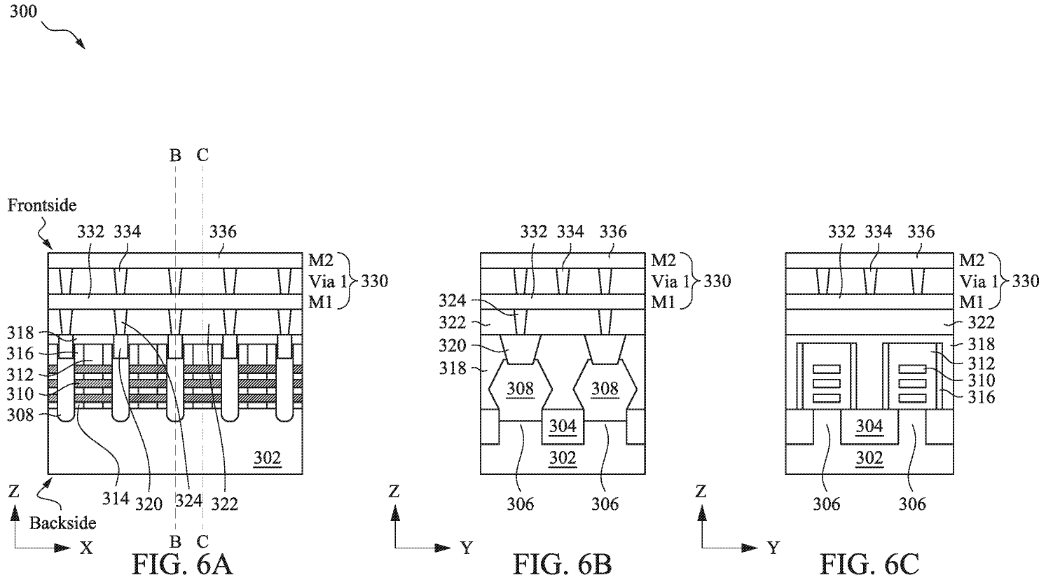

Method 200 is described below in conjunction with FIGS. 6A through 16C that illustrate various cross-sectional views of a testline structure (or structure) 300 at various steps of fabrication according to the method 200, in accordance with some embodiments. FIGS. 6A through 16C have been simplified for the sake of clarity to better understand the inventive concepts of the present disclosure. Additional features can be added in the structure 300, and some of the features described below can be replaced, modified, or eliminated in other embodiments of the structure 300. In some embodiments, the structure 300 is substantially similar to the testline structure 130 depicted above with reference to FIGS. 1-4.

Further, the details of the structure 300 and fabrication methods thereof are described below in conjunction with an exemplary process of making a GAA device, according to some embodiments. A GAA device refers to a device having vertically-stacked horizontally-oriented multi-channel transistors, such as nanowire transistors and nanosheet transistors. GAA devices are promising candidates to take CMOS to the next stage of the roadmap due to their better gate control ability, lower leakage current, and fully FinFET device layout compatibility. For the purposes of simplicity, the present disclosure uses GAA devices as an example. Those of ordinary skill in the art should appreciate that they may readily use the present disclosure as a basis for designing or modifying other processes and structures (such as FinFET devices) for carrying out the same purposes and/or achieving the same advantages of the embodiments introduced herein.

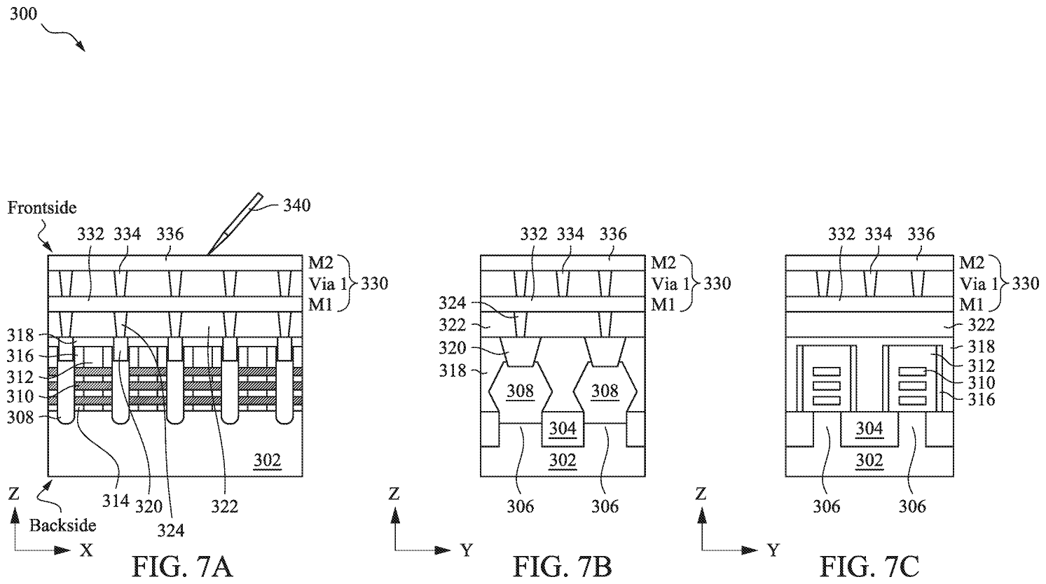

At operation 202, the method 200 (FIG. 5) provides a structure 300 having a substrate 302 and transistors (e.g., non-functional transistors and functional transistors) built on a frontside of the substrate 302. FIG. 6A illustrates a cross-sectional view of the structure 300 along a lengthwise direction of the channel layers of the transistors. FIG. 6B illustrates a cross-sectional view of the structure 300 along a B-B cutline in FIG. 6A, which is a cut into the sour/drain regions of the transistors. FIG. 6C illustrates a cross-sectional view of the structure 300 along a C-C cutline in FIG. 6a, which is a cut into gate regions of the transistors. The B-B cutlines and C-C cutlines in FIGS. 7A through 16C are similarly configured.

Still referring to FIGS. 6A-6C, the structure 300 includes the substrate 302 at its backside and various elements built on the front surface of the substrate 302. These elements include an isolation structure 304 over the substrate 302, semiconductor fins (or fins) 306 extending from the substrate 302 and adjacent to the isolation structure 304, epitaxial source/drain (S/D) features (or S/D features) 308 over the fins 306, one or more semiconductor channel layers (or channel layers) 310 suspended over the fins 306 and connecting two S/D features 308, and gate stacks 312 between two S/D features 308 and wrapping around each of the channel layers 310. The structure 300 further includes inner spacers 314 between the S/D features 308 and the gate stacks 312, (outer) gate spacers 316 over sidewalls of the gate stacks 312 and over the topmost channel layer 310, a first inter-layer dielectric (ILD) layer 318 adjacent to the gate spacers 316 and over the S/D features 308 and the gate stacks 212. The structure 300 may further include a contact etch stop layer (CESL) (not shown) under the first ILD layer 318. Over the S/D features 308, the structure 300 further includes S/D contacts 320 disposed over the S/D features 308, a second ILD layer 322 disposed over the first ILD layer 318 and the S/D contacts 320, and contact vias 324 disposed over the S/D contacts 320. The structure 300 further includes an interconnect structure 330 over the second ILD layer 322. The interconnect structure 330 includes a plurality of insulating layers, which may be inter-metal dielectric (IMD) layers. Each of the insulating layers includes conductive features, such as metal pieces (metal pads) and vias formed therein. In the illustrated embodiment, the interconnect structure 330 includes a metal pad 332 formed in the first level metal layer (M1) and over the contact vias 324, an array of vias 334 formed in the first level via layer (Via 1) and over the metal pad 332, and a metal pad 336 formed in the second level metal layer (M2) and over the vias 334. The metal pads may have a square shape, rectangular shape, circular shape, oval shape, or other suitable shapes from a top view. Area of each metal pad may range from about 100 um² to about 10,000 um². The various elements of the structure 300 are further described below.

In some embodiments, the substrate 302 is a bulk silicon substrate (i.e., including bulk single-crystalline silicon). The substrate 302 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In an alternative embodiment, substrate 302 is a semiconductor-on-insulator substrate, such as a silicon-on-insulator (SOI) substrate, a silicon germanium-on-insulator (SGOI) substrate, or a germanium-on-insulator (GOI) substrate.

In some embodiments, the fins 306 may include silicon, silicon germanium, germanium, or other suitable semiconductor, and may be doped n-type or p-type dopants. The fins 306 may be patterned by any suitable method. For example, the fins 306 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used as a masking element for patterning the fins 306. For example, the masking element may be used for etching recesses into semiconductor layers over or in the substrate 302, leaving the fins 306 on the substrate 302. The etching process may include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant. Numerous other embodiments of methods to form the fins 306 may be suitable.

The isolation structure 304 may include silicon oxide, silicon nitride, silicon oxynitride, other suitable isolation material (for example, including silicon, oxygen, nitrogen, carbon, or other suitable isolation constituent), or combinations thereof. The isolation structure 304 can include different structures, such as shallow trench isolation (STI) features and/or deep trench isolation (DTI) features. In an embodiment, the isolation structure 304 can be formed by filling the trenches between fins 306 with insulator material (for example, by using a CVD process or a spin-on glass process), performing a chemical mechanical polishing (CMP) process to remove excessive insulator material and/or planarize a top surface of the insulator material layer, and etching back the insulator material layer to form the isolation structure 304. In some embodiments, the isolation structure 304 include multiple dielectric layers, such as a silicon nitride layer disposed over a thermal oxide liner layer.

The S/D features 308 include epitaxially grown semiconductor materials such as epitaxially grown silicon, germanium, or silicon germanium. The S/D features 308 can be formed by any epitaxy processes including chemical vapor deposition (CVD) techniques (for example, vapor phase epitaxy and/or Ultra-High Vacuum CVD), molecular beam epitaxy, other suitable epitaxial growth processes, or combinations thereof. The S/D features 308 may be doped with n-type dopants and/or p-type dopants. In some embodiments, for n-type transistors, the S/D features 308 include silicon and can be doped with carbon, phosphorous, arsenic, other n-type dopant, or combinations thereof (for example, forming Si:C epitaxial S/D features, Si:P epitaxial S/D features, or Si:C:P epitaxial S/D features). In some embodiments, for p-type transistors, the S/D features 308 include silicon germanium or germanium, and can be doped with boron, other p-type dopant, or combinations thereof (for example, forming Si:Ge:B epitaxial S/D features). The S/D features 308 may include multiple epitaxial semiconductor layers having different levels of dopant density. In some embodiments, annealing processes (e.g., rapid thermal annealing (RTA) and/or laser annealing) are performed to activate dopants in the S/D features 308.

In some embodiments, the channel layers 310 include a semiconductor material suitable for transistor channels, such as silicon, silicon germanium, or other semiconductor material(s). The channel layers 310 may be in the shape of rods, bars, sheets, or other shapes in various embodiments. In an embodiment, the channel layers 310 are initially part of a stack of semiconductor layers that include the channel layers 310 and other sacrificial semiconductor layers alternately stacked layer-by-layer. The sacrificial semiconductor layers and the channel layers 310 include different material compositions (such as different semiconductor materials, different constituent atomic percentages, and/or different constituent weight percentages) to achieve etching selectivity. During a gate replacement process to form the gate stacks 312, the sacrificial semiconductor layers are selectively removed, leaving the channel layers 310 suspended over the fins 306.

In some embodiments, the inner spacers 314 include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the inner spacers 314 include a low-k dielectric material, such as those described herein. The inner spacers 314 may be formed by deposition and etching processes. For example, after S/D trenches are etched and before the S/D features 308 are epitaxially grown from the S/D trenches, an etch process may be used to recess the sacrificial semiconductor layers between the adjacent channel layers 310 to form gaps vertically between the adjacent channel layers 310. Then, one or more dielectric materials are deposited (using CVD or ALD for example) to fill the gaps. Another etching process is performed to remove the dielectric materials outside the gaps, thereby forming the inner spacers 314.

In some embodiments, the gate stacks 312 include a gate dielectric layer and a gate electrode layer. The gate dielectric layer may include a high-k dielectric material such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or combinations thereof. High-k dielectric material generally refers to dielectric materials having a high dielectric constant, for example, greater than that of silicon oxide (k≈3.9). The gate dielectric layer may be formed by chemical oxidation, thermal oxidation, atomic layer deposition (ALD), chemical vapor deposition (CVD), and/or other suitable methods. In some embodiments, the gate stacks 312 further includes an interfacial layer between the gate dielectric layer and the channel layers 310. The interfacial layer may include silicon dioxide, silicon oxynitride, or other suitable materials. In some embodiments, the gate electrode layer includes an n-type or a p-type work function layer and a metal fill layer. For example, an n-type work function layer may comprise a metal with sufficiently low effective work function such as titanium, aluminum, tantalum carbide, tantalum carbide nitride, tantalum silicon nitride, or combinations thereof. For example, a p-type work function layer may comprise a metal with a sufficiently large effective work function, such as titanium nitride, tantalum nitride, ruthenium, molybdenum, tungsten, platinum, or combinations thereof. For example, a metal fill layer may include aluminum, tungsten, cobalt, copper, and/or other suitable materials. The gate electrode layer may be formed by CVD, PVD, plating, and/or other suitable processes. Since the gate stacks 312 includes a high-k dielectric layer and metal layer(s), it is also referred to as a high-k metal gate.

In some embodiments, the gate spacers 316 include a dielectric material such as a dielectric material including silicon, oxygen, carbon, nitrogen, other suitable material, or combinations thereof (e.g., silicon oxide, silicon nitride, silicon oxynitride (SiON), silicon carbide, silicon carbon nitride (SiCN), silicon oxycarbide (SiOC), silicon oxycarbon nitride (SiOCN)). In embodiments, the gate spacers 316 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s). For example, a dielectric layer including silicon and nitrogen, such as a silicon nitride layer, can be deposited over a dummy gate stack (which is subsequently replaced by the high-k metal gate 312) and subsequently etched (e.g., anisotropically etched) to form the gate spacers 316. In some embodiments, the gate spacers 316 include a multi-layer structure, such as a first dielectric layer that includes silicon nitride and a second dielectric layer that includes silicon oxide. In some embodiments, more than one set of spacers, such as seal spacers, offset spacers, sacrificial spacers, dummy spacers, and/or main spacers, are formed adjacent to the gate stacks 312. In embodiments, the gate spacers 316 may have a thickness of about 1 nm to about 40 nm, for example.

In some embodiments, the first ILD layer 316 may comprise tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The first ILD layer 316 may be formed by PE-CVD (plasma enhanced CVD), F-CVD (flowable CVD), or other suitable methods. In embodiments, if a CESL is presented, the CESL may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods.

In some embodiments, the S/D contacts 320 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer is omitted in the S/D contacts 320. In some embodiments, a silicide feature (not shown) may be formed between the S/D contacts 320 and the S/D features 308 to reduce contact resistance. The silicide feature, if presented, may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

In some embodiments, the second ILD layer 322 is a flowable film formed by FCVD. Although any suitable material, such as low-dielectric constant (low-k) materials having a k-value less than about 4.5 (e.g., between about 2.5 and about 4.5) may be utilized. The second ILD layer 322 may include different material composition from the first ILD layer 318. For example, a dielectric constant of the second ILD layer 322 may be lower than the first ILD layer 318. In some embodiments, the second ILD layer 322 is formed of a dielectric material such as PSG, BSG, BPSG, USG, or the like, and may be deposited by any suitable method, such as CVD, PECVD, or the like. In some embodiments, the second ILD layer 322 may comprise silicon oxide (SiO), hafnium silicide (HfSi), silicon oxycarbide (SiOC), aluminum oxide (AlO), zirconium silicide (ZrSi), aluminum oxynitride (AlON), zirconium oxide (ZrO), hafnium oxide (HfO), titanium oxide (TiO), zirconium aluminum oxide (ZrAlO), zinc oxide (ZnO), tantalum oxide (TaO), lanthanum oxide (LaO), yttrium oxide (YO), tantalum carbonitride (TaCN), silicon nitride (SiN), silicon oxycarbonitride (SiOCN), silicon (Si), zirconium nitride (ZrN), silicon carbonitride (SiCN), combinations or multiple layers thereof, or the like.

In an embodiment, the S/D contact vias 324 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer is omitted in the S/D contact vias 324.

In some embodiments, the insulating layers in the interconnect structure 330 may be formed from a low-k dielectric material having a k-value between about 2.5 and about 4.5. The insulating layers may be formed from an extra-low-k (ELK) dielectric material having a k-value of less than about 2.5. In some embodiments, the insulating layers may be formed from an oxygen-containing and/or carbon containing low-k dielectric material, Hydrogen SilsesQuioxane (HSQ), MethylSilsesQuioxane (MSQ), the like, or a combination thereof. In some embodiments, some or all of insulating layers are formed of dielectric materials such as silicon oxide, silicon carbide (SiC), silicon carbonitride (SiCN), silicon oxycarbonitride (SiOCN), or the like. In some embodiments, etch stop layers (not shown), which may be formed of silicon carbide, silicon nitride, or the like, are formed between adjacent insulating layers. In some embodiments, the insulating layers are formed from a porous material such as SiOCN, SiCN, SiOC, SiOCH, or the like, and may be formed by spin-on coating or a deposition process such as plasma enhanced chemical vapor deposition (PECVD), CVD, PVD, or the like. In some embodiments, the interconnect structure 330 may include one or more other types of layers, such as diffusion barrier layers (not shown).

In some embodiments, the metal pads and vias in the interconnect structure 330 may be formed using a single and/or a dual damascene process, a via-first process, or a metal-first process. In an embodiment, an insulating layer is formed, and openings (not shown) are formed therein using acceptable photolithography and etching techniques. Diffusion barrier layers (not shown) may be formed in the openings and may include a material such as TaN, Ta, TiN, Ti, CoW, or the like, and may be formed in the openings using a deposition process such as CVD, Atomic Layer Deposition (ALD), or the like. A conductive material may be formed in the openings from copper, aluminum, nickel, tungsten, cobalt, silver, combinations thereof, or the like, and may be formed over the diffusion barrier layers in the openings using an electro-chemical plating process, CVD, ALD, PVD, the like, or a combination thereof. After formation of the conductive material, excess conductive material may be removed using, for example, a planarization process such as CMP, thereby leaving conductive features in the openings of the respective insulating layer. The process may then be repeated to form additional insulating layers and conductive features therein. The stacked metal pads in the interconnect structure 330 are connected to the S/D features 308 through the contact vias 324 and the S/D contacts 320. As a comparison, not like other gate stacks in a circuit region or gate stacks in a DUT, the gate stacks 312 in a probe pad structure portion of the structure 300 are floating without gate contacts bringing electrical connections to any interconnect structure. Therefore, the transistors in the probe pad structure portion of the structure 300 are non-functional transistors.

At operation 204, the method 200 (FIG. 5) may optionally perform an inter-metal wafer acceptance test (WAT) with probe needle(s) 340, such as shown in FIGS. 7A-7C. The inter-metal WAT is performed before the dies are completed to early determine the acceptance rate of the semiconductor wafer. After passing the inter-metal WAT, further fabrication processes may be performed on the semiconductor wafer. On the contrary, if the inter-metal WAT is not passed, the semiconductor wafer may be considered as a failure wafer and further fabrication process is ceased to avoid unnecessary manufacturing cost. In some embodiments, the inter-metal WAT may be performed after the metal layer M1 and/or M2 is formed and utilize structures formed in M1 and/or M2 (e.g., DUT 134 in FIG. 3) as DUTs or other features formed in underneath semiconductor layer (e.g., functional transistors in test pattern areas) as DUTs. Accordingly, the inter-metal WAT may facilitate to inspect the failure wafer in the middle stage of the fabrication process. Probe needle(s) 340 may land on the topmost metal pad of structure 300 to stimulate DUTs underneath. The probe needle(s) 340 may be a part of a probe card that includes multiple probe needles which, for example, may be connected to a testing equipment.

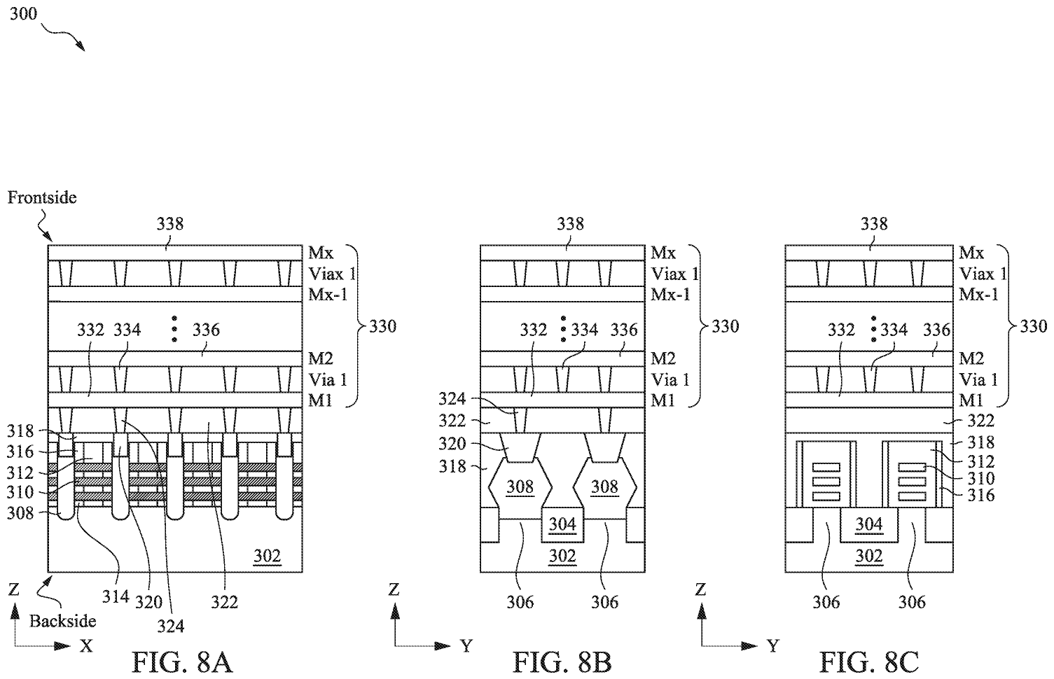

If inter-metal WAT is performed and passed, the method 200 (FIG. 5) proceeds to operation 206. Alternatively, the method 200 may skip operation 204 and proceed from operation 202 to operation 206. At operation 206, the method 200 further forms metal pieces (metal pads) in higher metal layers and vias therebetween in the interconnect structure 330, which are positioned above the metal pads 332 and 336 in the lower metal layers, such as shown in FIGS. 8A-8C. In some embodiments, there are totally about four (Mx=M4) to about eleven (Mx=M11) metal layers in the interconnect structure 330. The metal pads and vias formed at operation 206 may be substantially similar to the metal pads 332, 336 and via 334 discussed above. In some embodiments, the topmost insulating layer and the topmost metal pad 338 formed therein may be formed having a thickness greater than a thickness of the other insulating layers of the interconnect structure 330. This may be for enhancing mechanical strength of the topmost metal pad 338, as the topmost metal pad 338 is functioned as a frontside probe pad in further WAT. In some embodiments, metallic materials of the frontside probe pad and the metal pieces in underneath metal layers (M1, M2, . . . Mx−1) may be different. For example, the frontside probe pad may include AlCu or NiPdAu—Cu, and the metal pieces in underneath metal layers may include tungsten (W), cobalt (Co), molybdenum (Mo), ruthenium (Ru), nickel (Ni), copper (Cu), or other suitable metallic material. In some embodiments, one or more of the frontside probe pads are dummy probe pads in a testline structure that are electrically isolated from any DUT. Dummy probe pads may be formed to balance metal density in a testline structure. Dummy probe pads may also be electrically isolated from the S/D features 308 underneath (e.g., without the array of contact vias 324).

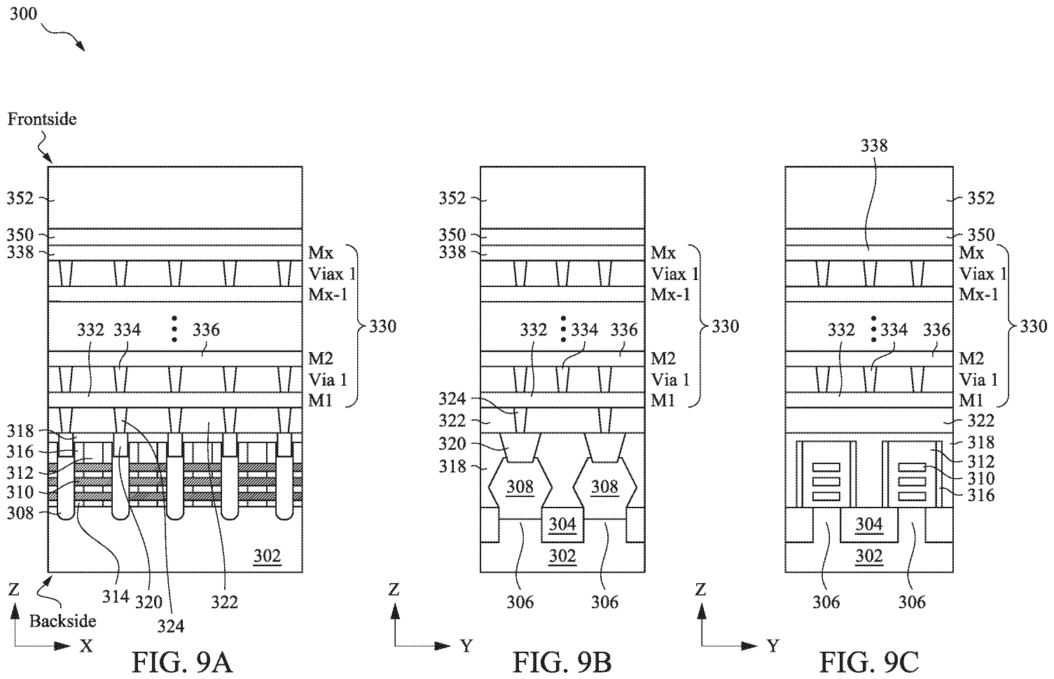

At operation 208, the method 200 (FIG. 5) attaches the frontside of the structure 300 to a carrier 352, such as shown in FIGS. 9A-9C. The carrier 352 may be a silicon wafer in some embodiments. The operation 208 may use any suitable attaching processes, such as direct bonding, hybrid bonding, using adhesive, or other bonding methods. In some embodiments, the frontside of the structure 300 is attached to the carrier 352 through an adhesive layer 350. In some embodiments, the adhesive layer 350 comprises a die attach film (DAF) such as an epoxy resin, a phenol resin, acrylic rubber, silica filler, or a combination thereof, and is applied using a lamination technique. The operation 208 may further include alignment, annealing, and/or other processes.

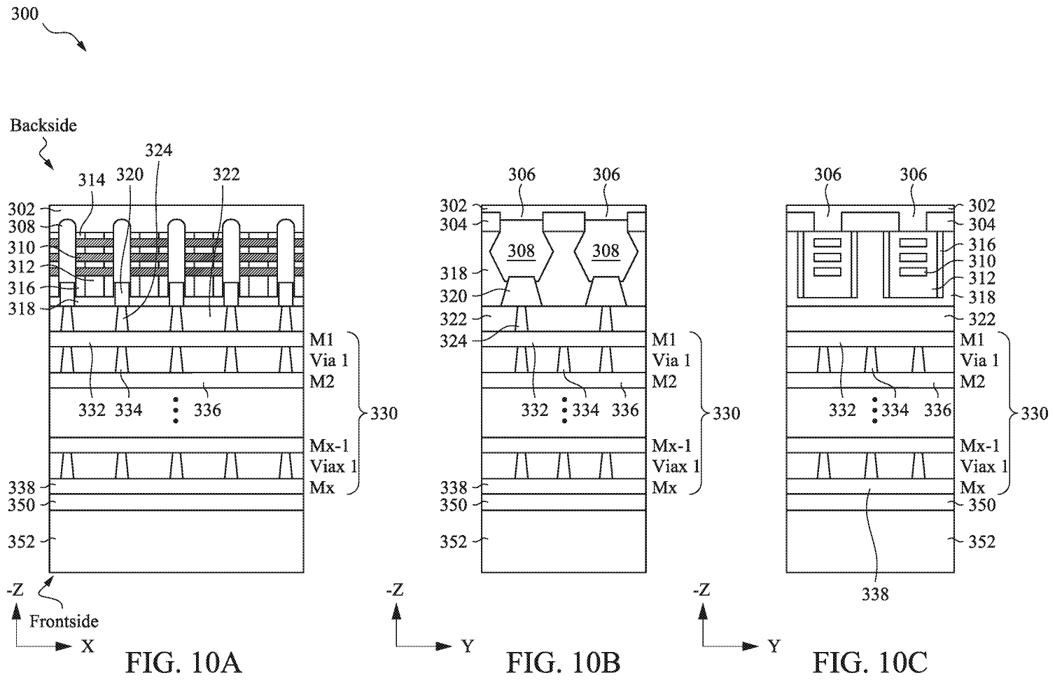

At operation 210, the method 200 (FIG. 5) flips the structure 300, such as shown in FIGS. 10A-10C. This makes the structure 300 accessible from the backside of the structure 300 for further processing. In FIGS. 10A-15C, the “z” direction points from the backside of the structure 300 to the frontside of the structure 300, while the “−z” direction points from the frontside of the structure 300 to the backside of the structure 300. The method 200 at the operation 210 also thins down the substrate 302 from the backside of the structure 300. In the depicted embodiment, the thinned substrate 302 remains covering the isolation structure 304. Alternatively, at the conclusion of the operation 210, the fins 306 and the isolation structure 304 may be exposed from the backside of the structure 300. The thinning process may include a mechanical grinding process and/or a chemical thinning process. A substantial amount of substrate material may be first removed from the substrate 302 during a mechanical grinding process. Afterwards, a chemical thinning process may apply an etching chemical to the backside of the substrate 302 to further thin down the substrate 302.

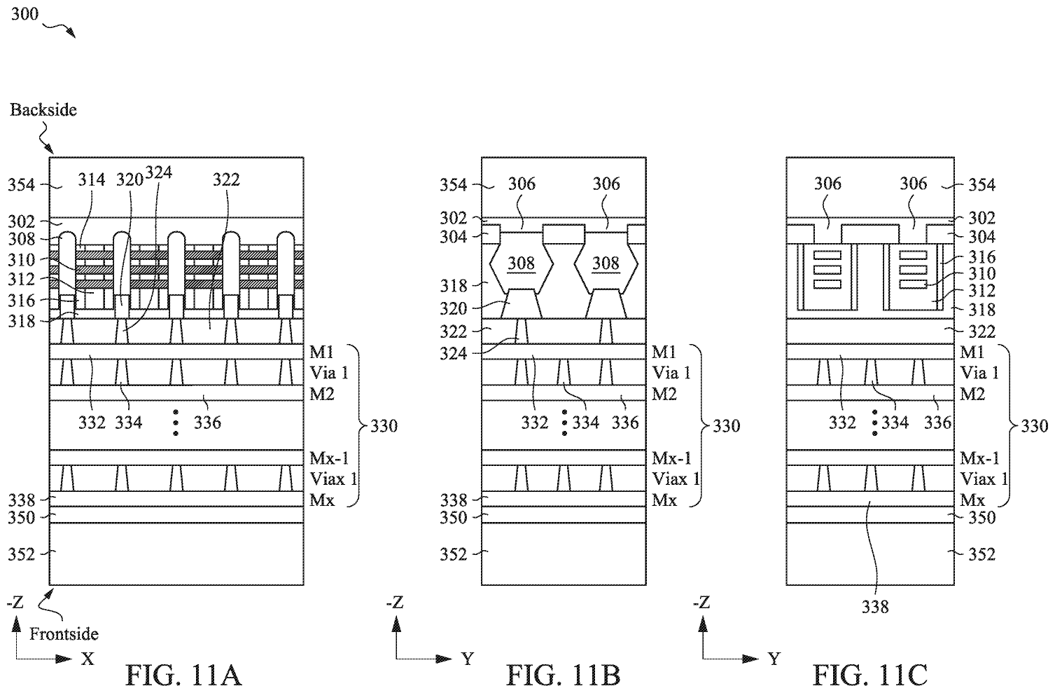

At operation 212, the method 200 (FIG. 5) deposits a dielectric layer 354 over the thinned substrate 302 on the backside of the structure 300, such as shown in FIGS. 11A-11C. If the isolation structure 304 is exposed at the conclusion of the operation 210, the dielectric layer 354 is also in contact with the isolation structure 304. The dielectric layer 354 is also referred to as a backside dielectric layer 354. The backside dielectric layer 354 may be formed from a low-k dielectric material having a k-value lower than about 4.5 (e.g., between about 2.5 and about 4.5). Alternatively, the insulating layers may be formed from an extra-low-k (ELK) dielectric material having a k-value of less than 2.5. In some embodiments, the backside dielectric layer 354 may be formed from an oxygen-containing and/or carbon containing low-k dielectric material, Hydrogen SilsesQuioxane (HSQ), MethylSilsesQuioxane (MSQ), the like, or a combination thereof. In some embodiments, the backside dielectric layer 354 may include one or more of La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s), and may be formed by PE-CVD, F-CVD or other suitable methods. At the conclusions of the operation 212, the backside dielectric layer 354 may be planarized by a planarization process, such as a chemical mechanical polishing (CMP) process.

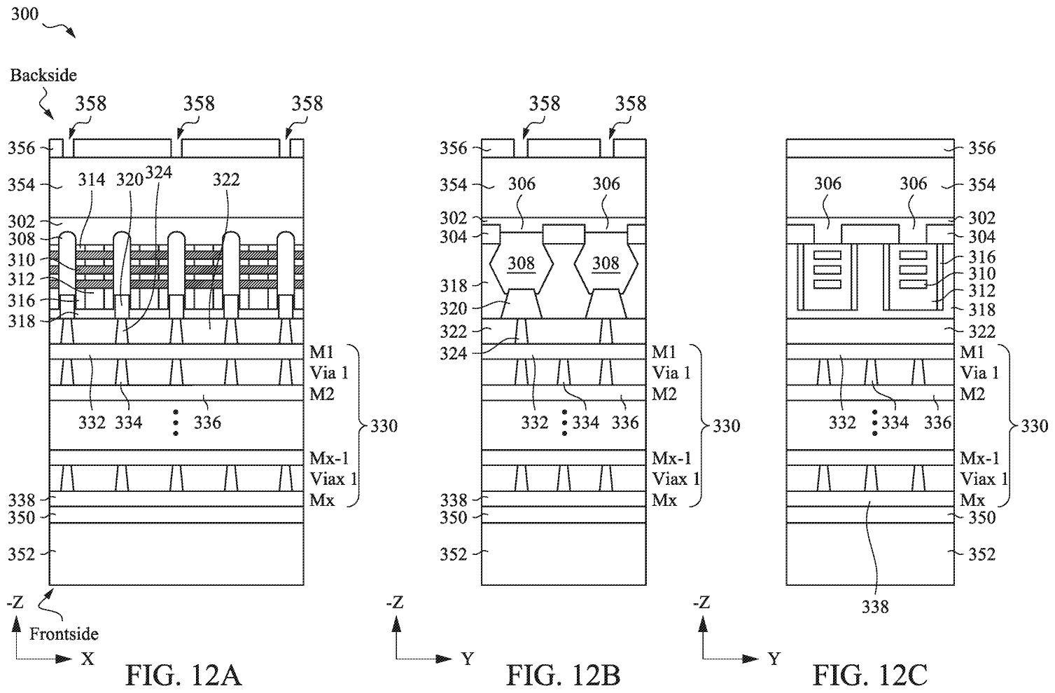

At operation 214, the method 200 (FIG. 5) forms an etch mask 356 over the backside of the structure 300, such as shown in FIGS. 12A-12C. The etch mask 356 provides openings 358 over the backside of the S/D features 308 that are to be connected to backside contact vias and backside metal pads. In the illustrated embodiment, the openings 358 are provided over the backside of the S/D features 308 while the backside of the gate stacks 312 are covered by the etch mask 356.

In various embodiments, the openings 358 may be provided over the backside of drain features only, source features only, or both source and drain features. In some embodiments, the openings 358 are formed over each of the S/D features 308 in a probe pad structure, such that the amount of to-be-formed backside contact vias equals the amount of frontside contact vias 324. Alternatively, such as in the depicted embodiment, the openings 358 are formed on backside of not all but every other S/D features 308 along the X-direction. As the to-be-formed backside contact vias have larger height and larger aspect ratio than the frontside contact vias 324, an increased pitch allows the to-be-formed backside via hole to be opened wider than the frontside contact vias 324, which facilitates the metal deposition in forming backside contact vias without causing voids.

The etch mask 356 includes a material that is different than a material of the backside dielectric layer 354 to achieve etching selectivity during backside via hole etching. For example, the etch mask 356 includes a resist material (and thus may be referred to as a patterned resist layer and/or a patterned photoresist layer). In some embodiments, the etch mask 356 has a multi-layer structure, such as a resist layer disposed over an anti-reflective coating (ARC) layer and/or a hard mask layer comprising silicon nitride or silicon oxide. The present disclosure contemplates other materials for the etch mask 356, so long as etching selectivity is achieved during the etching of the backside dielectric layer 354. In some embodiments, operation 214 uses a lithography process that includes forming a resist layer over the backside of the structure 300 (e.g., by spin coating), performing a pre-exposure baking process, performing an exposure process using a mask, performing a post-exposure baking process, and performing a developing process. During the exposure process, the resist layer is exposed to radiation energy (e.g., UV light, DUV light, or EUV light), where the mask blocks, transmits, and/or reflects radiation to the resist layer depending on a mask pattern of the mask and/or mask type (e.g., binary mask, phase shift mask, or EUV mask), such that an image is projected onto the resist layer that corresponds with the mask pattern. Since the resist layer is sensitive to radiation energy, exposed portions of the resist layer chemically change, and exposed (or non-exposed) portions of the resist layer are dissolved during the developing process depending on characteristics of the resist layer and characteristics of a developing solution used in the developing process. After development, the patterned resist layer (e.g., the etch mask 356) includes a resist pattern that corresponds with the mask. Alternatively, the exposure process can be implemented or replaced by other methods, such as maskless lithography, e-beam writing, ion-beam writing, or combinations thereof.

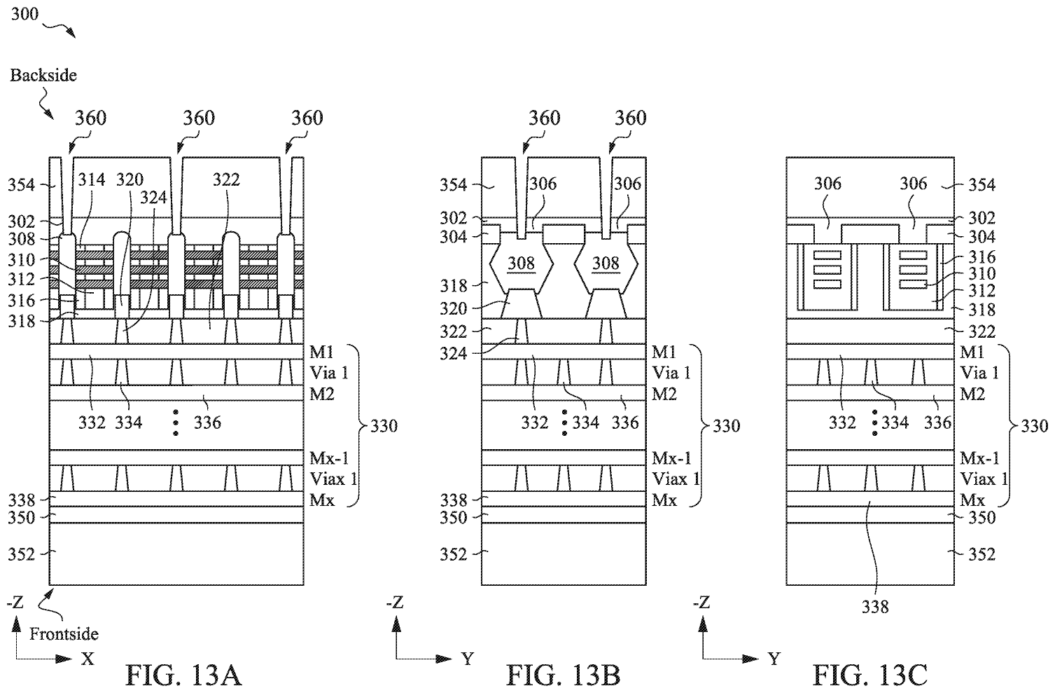

At operation 216, the method 200 (FIG. 5) etches the dielectric layer 354 through the etch mask 356 to form backside via holes 360. The etch mask 356 is subsequently removed, for example, by a resist stripping process or other suitable process. The resultant structure is shown in FIGS. 13A-13C according to an embodiment. The backside via holes 368 expose the S/D features 308. In the illustrated embodiment, the etching process also etches the exposed S/D feature 260 to recess it to a level that is below the backside surface of an adjacent S/D feature 308 that remains covered by the backside dielectric layer 354. The recessing is for preparing the exposed S/D features 308 for subsequent silicide formation. In some embodiments, the operation 216 may apply more than one etching processes. For example, it may apply a first etching process to selectively remove the backside dielectric layer 354, and then apply a second etching process to selectively recess the S/D features 308 to the desired level, where the first and the second etching processes use different etching parameters such as using different etchants. In an embodiment, the first etching process include a dry (plasma) etching process that is tuned to selectively etch the backside dielectric layer 354. In alternative embodiments, first etching process may use other types of etching (such as wet etching or reactive ion etching) as long as the etch selectivity between the layers is achieved as discussed above. The second etching process can be dry etching, wet etching, reactive ion etching, or other suitable etching methods, to selectively recess the exposed ones of the S/D features 308 to the desired level.

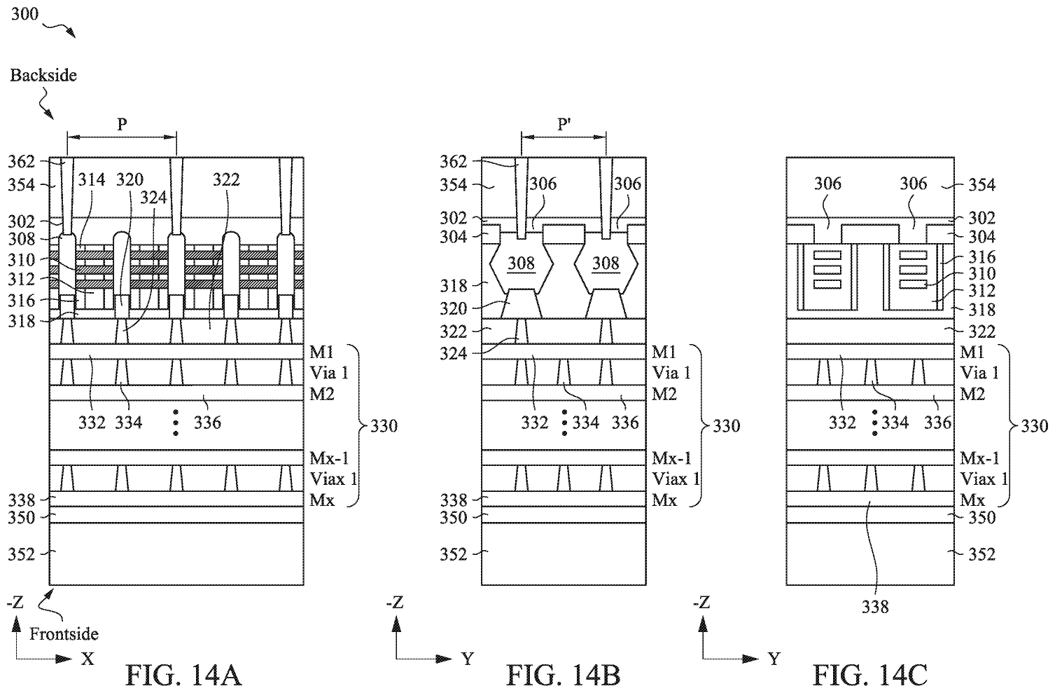

At operation 218, the method 200 (FIG. 5) forms backside contact vias 362 in the backside via holes 360. The resultant structure is shown in FIGS. 14A-14C. In an embodiment, the operation 218 first forms a silicide feature (not shown) in the backside via holes 360 by depositing one or more metals into the backside via holes 360, performing an annealing process to the structure 300 to cause reaction between the one or more metals and the exposed S/D features 308 to produce the silicide feature, and removing un-reacted portions of the one or more metals, leaving the silicide feature on the backside of the exposed S/D features 308. The one or more metals may include titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals) and may be deposited using CVD, PVD, ALD, or other suitable methods. The silicide feature may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. In an embodiment, the operation 218 then deposits the backside vias 362 over the silicide feature. The backside vias 362 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. At the conclusion of the operation 218, the method 200 performs a CMP process to remove excessive metallic materials from the backside of the structure 300.

As discussed above, a pitch of the backside contact vias 362 along the X-direction (denoted as P) may equal to that of the frontside contact vias 324; alternatively, P may be smaller (e.g., about half as depicted in FIG. 14A) than that of the frontside contact vias 324. In some embodiments, P may be smaller than about 50 nm, and a lateral distance between a backside contact via 362 and adjacent gate stack 312 may be less than about 20 nm. As a comparison, a pitch of the backside contact vias 362 along the Y-direction (denoted as P′) may equal to that of the front side contact visas 324. Further, as discussed above, a height and an aspect ratio (height/width) of the backside contact vias 362 may be larger than those of the frontside contact vias 324. In some embodiments, a width of the backside contact vias 362 is also larger than that of the frontside contact vias 324 due to a larger pitch, which facilitates metal deposition in high-aspect-ratio holes. In some embodiments, a height of the backside contact vias 362 is larger than about 35 nm.

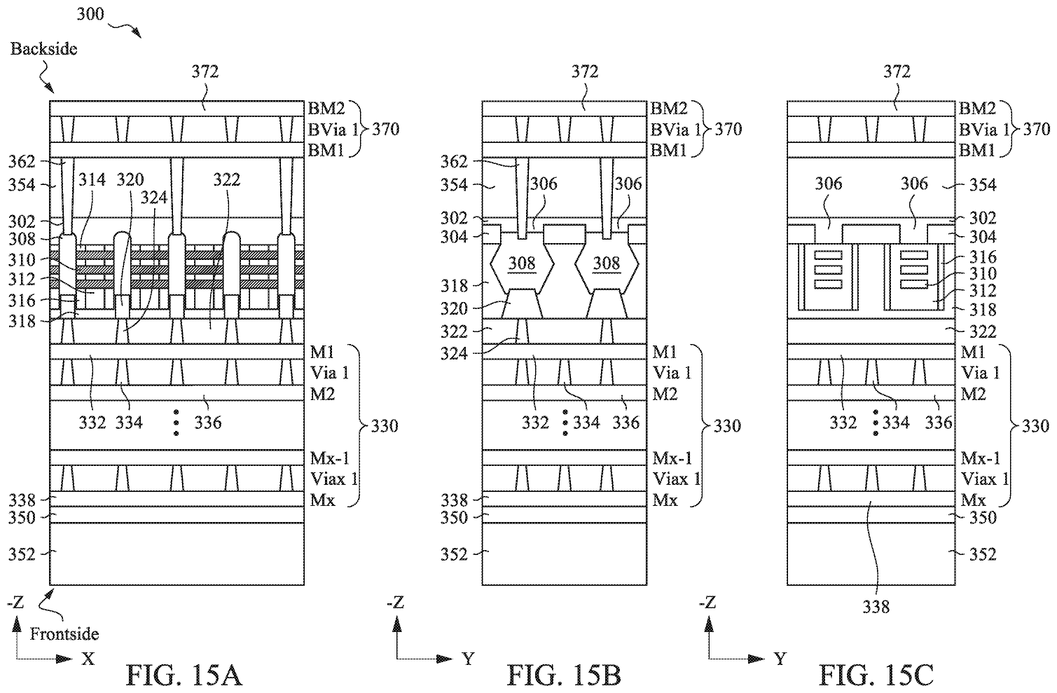

At operation 220, the method 200 (FIG. 1B) forms a backside interconnect structure 370 on the backside of the structure 300. The resultant structure is shown in FIGS. 15A-15C according to an embodiment. The backside contact vias 362 is electrically connected to the metal pad formed in the backside first level metal layer (BM1) of the backside interconnect structure 370. In the depicted embodiment, the backside interconnect structure 370 includes metal pads formed in the backside second level metal layer (BM2) and BM1 and backside vias formed therebetween (BVia 1). Alternatively, the backside interconnect structure 370 may have more or less than two backside metal layers. In some embodiments, the frontside interconnect structure 330 has more metal layers and a larger height than the backside interconnect structure 370. In some embodiments, the frontside interconnect structure 330 has the same number of metal layers and similar height as the backside interconnect structure 370.

In some embodiments, the backside interconnect structure 370 includes insulating layers formed from a low-k dielectric material having a k-value lower than about 4.5 (e.g., between about 2.5 and about 4.5). The insulating layers may be formed from an extra-low-k (ELK) dielectric material having a k-value of less than 2.5. In some embodiments, the insulating layers may be formed from an oxygen-containing and/or carbon containing low-k dielectric material, Hydrogen SilsesQuioxane (HSQ), MethylSilsesQuioxane (MSQ), the like, or a combination thereof. In some embodiments, some or all of insulating layers are formed of dielectric materials such as silicon oxide, silicon carbide (SiC), silicon carbonitride (SiCN), silicon oxycarbonitride (SiOCN), or the like. In some embodiments, the insulating layers are formed from a porous material such as SiOCN, SiCN, SiOC, SiOCH, or the like, and may be formed by spin-on coating or a deposition process such as plasma enhanced chemical vapor deposition (PECVD), CVD, PVD, or the like.

In some embodiments, the metal pads and vias in the backside interconnect structure 370 may be formed using a single and/or a dual damascene process, a via-first process, or a metal-first process. In an embodiment, an insulating layer is formed, and openings (not shown) are formed therein using acceptable photolithography and etching techniques. Diffusion barrier layers (not shown) may be formed in the openings and may include a material such as TaN, Ta, TiN, Ti, CoW, or the like, and may be formed in the openings using a deposition process such as CVD, Atomic Layer Deposition (ALD), or the like. A conductive material may be formed in the openings from copper, aluminum, nickel, tungsten, cobalt, silver, combinations thereof, or the like, and may be formed over the diffusion barrier layers in the openings using an electro-chemical plating process, CVD, ALD, PVD, the like, or a combination thereof. After formation of the conductive material, excess conductive material may be removed using, for example, a planarization process such as CMP, thereby leaving conductive features in the openings of the respective insulating layer. The process may then be repeated to form additional insulating layers and conductive features therein. The stacked metal pads in the backside interconnect structure 370 are connected to the S/D features 308 through the backside contact vias 362.

The metal pads in the backside interconnect structure 370 may have the same shape as the counterparts in the frontside interconnect structure 330, such as a square shape, rectangular shape, circular shape, oval shape, or other suitable shapes from a top view. In some embodiments, the bottommost insulating layer and the bottommost metal pad 372 formed therein may be formed having a thickness greater than a thickness of the other insulating layers of the backside interconnect structure 370. This may be for enhancing mechanical strength of the bottommost metal pad 372, as the bottommost metal pad 372 is functioned as a backside probe pad in further WAT. In some embodiments, metallic materials of the backsideside probe pad and the metal pieces in above metal layers (e.g., BM1) may be different. For example, the backside probe pad may include AlCu or NiPdAu—Cu, and the metal pieces in above metal layers may include tungsten (W), cobalt (Co), molybdenum (Mo), ruthenium (Ru), nickel (Ni), copper (Cu), or other suitable metallic material. In some embodiments, one or more of the backside probe pads are dummy probe pads in a testline structure that are electrically isolated from any DUT. Dummy probe pads may be formed to balance metal density in a testline structure. Dummy probe pads may also be electrically isolated from the S/D features 308 above (e.g., without the array of backside contact vias 362).

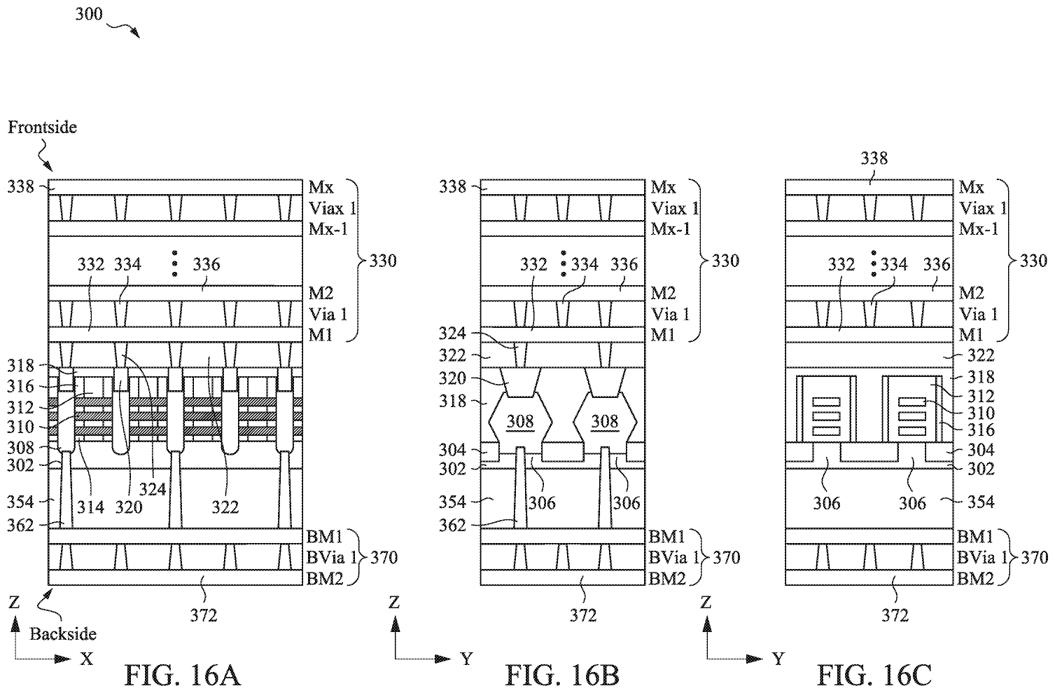

At operation 222, the method 200 (FIG. 5) performs further fabrication processes to the structure 300. For example, it may flip the structure 300 and remove the carrier 352, such as shown in FIGS. 16A-16C. The method 200 at the operation 222 may also perform other back-end-of-line (BEOL) processes including forming passivation layers in the circuit region, perform WAT and/or FA tests from both the frontside and the backside of the structure 300, and singulate and package the dies. As discussed above, depending on scribing process, probe pad structures may remain in the dies.

In view of the above, the testline structure in the semiconductor device includes frontside probe pads and backside probe pads, which meets test needs for advanced semiconductor devices having backside power rails. The backside probe pads also provide capability of housing more DUTs on an ever-shrunk testline area, such as housing more DUTs on the backside of the semiconductor devices. Embodiments of the present disclosure can be readily integrated into existing semiconductor manufacturing processes.

In one example aspect, the present disclosure is directed to a testline structure of a semiconductor device. The testline structure includes a substrate layer, a frontside insulating layer atop the substrate layer, a backside insulating layer under the substrate layer, and a probe pad structure vertically extending through the frontside insulating layer, the substrate layer, and the backside insulating layer, the probe pad structure including a frontside probe pad in the frontside insulating layer and a backside probe pad in the backside insulating layer. In some embodiments, the semiconductor device is a wafer, and the testline structure is located in a scribe line region of the wafer. In some embodiments, the semiconductor device is a packaged integrated circuit die, and the testline structure is located aside of a circuit region of the packaged integrated circuit die. In some embodiments, the testline structure further includes a device under test (DUT) in electrical connection with the probe pad structure. In some embodiments, the DUT is formed in the frontside insulating layer. In some embodiments, the DUT is formed in the backside insulating layer. In some embodiments, the probe pad structure also includes a plurality of doped epitaxial features in the substrate layer, frontside contact vias coupling the doped epitaxial features to the frontside probe pad, and backside contact vias coupling the doped epitaxial features to the backside probe pad. In some embodiments, a pitch of the backside contact vias is larger than a pitch of the frontside contact vias. In some embodiments, the probe pad structure also includes gate stacks between adjacent ones of the doped epitaxial features, the gate stacks being electrically floating. In some embodiments, the frontside probe pad and the backside probe pad include metallic compositions different from other metal pieces of the probe pad structure formed in the frontside insulating layer and the backside insulating layer.

In another example aspect, the present disclosure is directed to a semiconductor device. The semiconductor device a circuit region having a frontside power rail in a frontside of the semiconductor device and a backside power rail in a backside of the semiconductor device, a seal ring region surrounding the circuit region, and a testline region aside the seal ring region. The testline region includes a frontside metal pad in the frontside of the semiconductor device, a plurality of epitaxial features under the frontside metal pad, and a plurality of contact vias above the epitaxial features and electrically coupling the epitaxial features to the frontside metal pad. In some embodiments, the circuit region includes functional transistors, and the testline region includes non-functional transistors, and the epitaxial features are source/drain features of the non-functional transistors. In some embodiments, the non-functional transistors include gate stacks between adjacent ones of the epitaxial features, and the gate stacks are electrically floating. In some embodiments, the testline region also includes a backside metal pad formed in the backside of the semiconductor device, and a plurality of backside vias in contact with bottom surfaces of the epitaxial features and electrically coupling the epitaxial features to the backside metal pad. In some embodiments, the backside metal pad and the frontside metal pad have a same shape. In some embodiments, a height of the backside vias is larger than a height of the contact vias.

In yet another example aspect, the present disclosure is directed to a method. The method includes providing a structure having a frontside and a backside, the structure including a substrate, semiconductor channel layers over the substrate, source/drain features abutting the semiconductor channel layers, gate structures wrapping around the semiconductor channel layers, the substrate being at the backside of the structure and the gate structures are at the frontside of the structure, forming source/drain contacts on the source/drain features, forming contact vias on the source/drain contacts, forming a first interconnect structure on the contact vias, the first interconnect structure including a first probe pad at the frontside of the structure, forming backside vias under the source/drain features, and forming a second interconnect structure under the backside vias, the second interconnect structure including a second probe pad at the backside of the structure. In some embodiments, the method further includes after the forming of the first interconnect structure, flipping the structure, and prior to the forming of the backside vias, thinning the substrate from the backside of the structure. In some embodiments, the method further includes prior to the forming of the backside vias, performing an inter-metal wafer acceptance test (WAT) through the first probe pad. In some embodiments, the first interconnect structure also includes a first stacking via structure under the first probe pad, and the second interconnect structure also includes a second stacking via structure above the second probe pad.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A testline structure of a semiconductor device, comprising:
a substrate layer;
a frontside insulating layer atop the substrate layer;
a backside insulating layer under the substrate layer; and
a probe pad structure vertically extending through the frontside insulating layer, the substrate layer, and the backside insulating layer, wherein the probe pad structure includes a frontside probe pad in the frontside insulating layer and a backside probe pad in the backside insulating layer.

2. The testline structure of claim 1, wherein the semiconductor device is a wafer, and the testline structure is located in a scribe line region of the wafer.

3. The testline structure of claim 1, wherein the semiconductor device is a packaged integrated circuit die, and the testline structure is located aside of a circuit region of the packaged integrated circuit die.

4. The testline structure of claim 1, further comprising:
a device under test (DUT) in electrical connection with the probe pad structure.

5. The testline structure of claim 4, wherein the DUT is formed in the frontside insulating layer.

6. The testline structure of claim 4, wherein the DUT is formed in the backside insulating layer.

7. The testline structure of claim 1, wherein the probe pad structure also includes:
a plurality of doped epitaxial features in the substrate layer,
frontside contact vias coupling the doped epitaxial features to the frontside probe pad, and
backside contact vias coupling the doped epitaxial features to the backside probe pad.

8. The testline structure of claim 7, wherein a pitch of the backside contact vias is larger than a pitch of the frontside contact vias.

9. The testline structure of claim 7, wherein the probe pad structure also includes:
gate stacks between adjacent ones of the doped epitaxial features, wherein the gate stacks are electrically floating.

10. The testline structure of claim 1, wherein the frontside probe pad and the backside probe pad include metallic compositions different from other metal pieces of the probe pad structure formed in the frontside insulating layer and the backside insulating layer.

11. A semiconductor device, comprising:
a circuit region having a frontside power rail in a frontside of the semiconductor device and a backside power rail in a backside of the semiconductor device;
a seal ring region surrounding the circuit region; and
a testline region aside the seal ring region, wherein the testline region includes:
a frontside metal pad in the frontside of the semiconductor device,
a plurality of epitaxial features under the frontside metal pad, and
a plurality of contact vias above the epitaxial features and electrically coupling the epitaxial features to the frontside metal pad.

12. The semiconductor device of claim 11, wherein the circuit region includes functional transistors, and the testline region includes non-functional transistors, and wherein the epitaxial features are source/drain features of the non-functional transistors.

13. The semiconductor device of claim 12, wherein the non-functional transistors include gate stacks between adjacent ones of the epitaxial features, and the gate stacks are electrically floating.

14. The semiconductor device of claim 11, wherein the testline region also includes:
a backside metal pad in the backside of the semiconductor device, and
a plurality of backside vias in contact with bottom surfaces of the epitaxial features and electrically coupling the epitaxial features to the backside metal pad.

15. The semiconductor device of claim 14, wherein the backside metal pad and the frontside metal pad have a same shape.

16. The semiconductor device of claim 14, wherein a height of the backside vias is larger than a height of the contact vias.

17. A method, comprising:
providing a structure having a frontside and a backside, the structure including a substrate, semiconductor channel layers over the substrate, source/drain features abutting the semiconductor channel layers, gate structures wrapping around the semiconductor channel layers, wherein the substrate is at the backside of the structure and the gate structures are at the frontside of the structure;
forming source/drain contacts on the source/drain features;
forming contact vias on the source/drain contacts;
forming a first interconnect structure on the contact vias, the first interconnect structure including a first probe pad at the frontside of the structure;
forming backside vias under the source/drain features; and
forming a second interconnect structure under the backside vias, the second interconnect structure including a second probe pad at the backside of the structure.

18. The method of claim 17, further comprising:
after the forming of the first interconnect structure, flipping the structure; and
prior to the forming of the backside vias, thinning the substrate from the backside of the structure.

19. The method of claim 17, further comprising:
prior to the forming of the backside vias, performing an inter-metal wafer acceptance test (WAT) through the first probe pad.

20. The method of claim 17, wherein the first interconnect structure also includes a first stacking via structure under the first probe pad, and the second interconnect structure also includes a second stacking via structure above the second probe pad.
